(19) United States
(12) Patent Application Publication
(10) Pub. No.: US 2002/0173108 A1
(43) Pub. Date: Nov. 21, 2002

(54) Method of forming a LD MOS

(76) Inventors: Ching-Chun Huang, Tai-chun City (TW); Sheng-Hsiung Yang, Hsin-Chu City (TW)

Correspondence Address: NAIPO (NORTH AMERICA INTERNATIONAL PATENT OFFICE), P.O. BOX 506, MERRIFIELD, VA, 22116, US

(21) Appl. No.: 09/858,519

(22) Filed: May 17, 2001

(51) Int. Cl. H01L 21/8222

(52) U.S. Cl. 438/316

(57) ABSTRACT

A P-well and an N-well adjacent to the P-well are formed within a semiconductor substrate. A silicon nitride layer having an opening and a silicon oxide layer are then formed, respectively, on the semiconductor substrate. The silicon oxide layer fills the opening in the silicon nitride layer. Following that, a chemical mechanical polishing process removes portions of the silicon oxide layer to align the surface of the remaining silicon oxide layer with the surface of the silicon nitride layer to form an insulator. Subsequently, the silicon nitride layer is completely removed followed by forming a gate layer positioned on the P-well and N-well, a side of the gate layer being positioned on the surface of the insulator. Finally, an ion implantation process is performed to form N-type doping regions on the P-well and the N-well as a source and a drain of an LD MOS transistor, completing fabrication of the LD MOS transistor.

### BACKGROUND OF THE INVENTION

1. Field of the Invention

The present invention relates to a method of forming a metal-oxide semiconductor (MOS) transistor on a semiconductor wafer, and more particularly, to a method of forming a lateral diffused metal-oxide semiconductor (LD MOS) transistor on a semiconductor wafer.

2. Description of the Prior Art

Metal-oxide semiconductor (MOS) transistors that consume less power and that can be highly integrated are widely used in the semiconductor industry. When a proper voltage is inputted, MOS transistors can be used as a kind of switch to control the flow of electricity through a device. In high voltage circuits, such as the input and output terminals of electrical equipment, LD MOS transistors are commonly used because of their ability to withstand heavy loads. As the development of integrated circuits progresses, controlling the manufacturing process of LD MOS transistors becomes an increasingly important issue.

Please refer to FIGS. 1A to 1F. FIGS. 1A to 1F are cross-sectional diagrams of a method of forming a prior art LD MOS transistor. As shown in FIG. 1A, a semiconductor substrate 100 is first placed into a thermal oxidation furnace to perform a thermal oxidation process to grow a silicon oxide layer 120, around 200 to 400 angstroms (Å) thick, on the surface of the semiconductor substrate 100. The semiconductor substrate 100 is a P-type silicon substrate. The silicon oxide layer 120 functions as a pad oxide layer to promote adherence between a subsequent silicon nitride layer and the semiconductor substrate 100, and to reduce thermal stress on the silicon nitride layer. Also, the silicon oxide layer 120 functions as a sacrificial oxide layer in a subsequent ion implantation process to increase the scattering of ions so as to prevent channel effects.

Following that, a photoresist layer 150 is coated onto the semiconductor substrate 100, and a lithographic process is performed to define the ion implantation area of a P-well. An ion implantation process is performed to dope P-type dopants into the semiconductor substrate 100 to form a P-type doping region 110. Then the photoresist layer 150 is stripped.

As shown in FIG. 1B, the steps described above are performed again to form a photoresist layer 151 that defines the ion implantation area of an N-well. Then N-type dopants are doped into the semiconductor substrate 100 to form an N-type doping region 112 adjacent to the P-type doping region 110. Following that, the photoresist layer 151 is stripped.

As shown in FIG. 1C, a chemical vapor deposition (CVD) is performed to form a silicon nitride layer 130 on the silicon oxide layer 120. Thereafter, a lithographic process and an etching process are performed to form an opening 131 within the silicon nitride layer 130, the opening 131 connecting to the surface of the silicon oxide layer 120 and defining an area for the formation of a field oxide layer. Taking advantage of silicon nitride, which prevents diffusion of oxygen and water, the silicon nitride layer 130 is used as a mask in a local oxidation of silicon (LOCOS) process that forms the field oxide layer.

Then, as shown in FIG. 1D, a wet oxidation process is performed to grow a field oxide layer 121 in the presence of water and oxygen, simultaneously using thermal diffusion to drive the dopants in the P-type doping region 110 and the N-type doping region 112 into the semiconductor substrate 100 so as to form the P-well 110 and the N-well 112. Subsequently, the silicon nitride layer 130 is stripped using a heated phosphoric acid solution.

As shown in FIG. 1E, a gate oxide layer and a gate conductive layer of the LD MOS transistor are then formed. The residual silicon oxide layer 120 is removed completely using a wet etching process. Then, the silicon surface, which has suffered atmospheric exposure, is cleaned to ensure its quality. After the cleaning process, the semiconductor substrate 100 is placed into the thermal oxidation furnace again to form a silicon oxide layer 122, around 100 to 250 Å thick, on the active area using a dry oxidation process. A polysilicon layer 140, around 2000 to 3000 Å thick, is deposited onto the silicon oxide layer 122 using an LPCVD process. A thermal diffusion method or an ion implantation process is then performed to heavily dope the polysilicon layer 140 so as to reduce the resistivity of the polysilicon layer 140. Following that, a lithographic process is performed to form another photoresist layer 142 on the surface of the semiconductor substrate 100 to define the position for forming a gate.

Please refer to FIG. 1F. A dry etching process is performed to remove both the polysilicon layer 140 and the silicon oxide layer 122 that are not protected by the photoresist layer 142. The photoresist layer 142 is then stripped. The residual polysilicon layer 140 forms a gate 143, and the residual of the silicon oxide layer 122 functions as a gate oxide layer. Wherein, the gate 143 is positioned on a portion of both the P-well 110 and the N-well 112, and one side of the gate 143 is positioned atop the field oxide layer 121. Following that, a lithographic process and an ion implantation process are performed to heavily dope the P-well 110 and the N-well 112 so as to form N-type doping regions 144 and 146. The N-type doping region 144, functioning as a source, is adjacent to one side of the gate 143. The other N-type doping region 146, functioning as a drain, is adjacent to the field oxide layer 121. Finally, the fabrication process of the prior LD MOS transistor is completed.

In the method of forming the prior LD MOS transistor, a portion of the silicon oxide layer 120 under the silicon nitride layer 130 is oxidized due to the lateral diffusion of water and oxygen during the thermal oxidation process of forming the field oxide layer 121. Consequently, a bird's beak is formed in the field oxide layer 121 adjacent to the silicon nitride layer 130. Since the scale of the bird's beak cannot be precisely controlled, the length of the field oxide layer 121 is also not of a precise length.

In addition, the drain 146 is positioned beside the field oxide layer 121 according to the prior art. Hence, carriers drifting from the source 144 to the drain 146 must follow the drifting path 148 to detour round the bottom 124 of the field oxide layer, as shown in FIG. 1F, to reach the drain 146. In a brief, the channel length from the source 144 to the drain 146 is determined by the length of the field oxide layer 121. Since the length of the file oxide layer 121 formed by the thermal oxidation cannot be precisely controlled, the on-resistance of the LD MOS transistor cannot be precisely controlled either, affecting the entire electrical performance of the LD MOS transistor.

### SUMMARY OF THE INVENTION

It is therefore a primary objective of the present invention to provide a method of forming an LD MOS transistor on a semiconductor wafer to solve the above-mentioned problem.

According to the claimed invention, a P-well and an N-well adjacent to the P-well are first formed within a semiconductor substrate. A silicon nitride layer is then formed on the semiconductor substrate. Following that, a lithographic process is performed to form a photoresist layer on the silicon nitride layer, the photoresist layer being used to define a position of an insulator. Using the photoresist layer as a mask, an etching process is performed to form an opening in the silicon nitride layer. After the photoresist layer is stripped, a deposition process is performed to form a silicon oxide layer on the silicon nitride layer, the silicon oxide layer filling the opening in the silicon nitride layer. Subsequently, a chemical mechanical polishing (CMP) process is performed to remove portions of the silicon oxide layer to align the surface of the remaining silicon oxide layer with the surface of the silicon nitride layer. Wherein, the silicon oxide layer remaining in the opening in the silicon nitride layer forms the insulator. Subsequently, the silicon nitride layer is completely removed followed by forming a gate layer positioned on a portion of the surfaces of both the P-well and N-well, a side of the gate layer being positioned on the surface of the insulator. Finally, an ion implantation process is performed to form N-type doping regions on the P-well and the N-well, respectively. The N-type doping regions function as a source and a drain of the LD MOS transistor.

It is an advantage of the present invention method that the insulator is formed by deposition and the CMP processes, so difficulty in controlling the channel length by LOCOS in the prior art is effectively prevented. Since the channel length of the LD MOS transistor can be precisely controlled according to the present invention, the on-resistance can also be well controlled to improve the electrical performance of the LD MOS transistor.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1A to 1F are cross-sectional diagrams of a method of forming an LD MOS transistor according to the prior art.

FIGS. 2A to 2I are cross-sectional diagrams of a method of forming an LD MOS transistor according to the present invention.

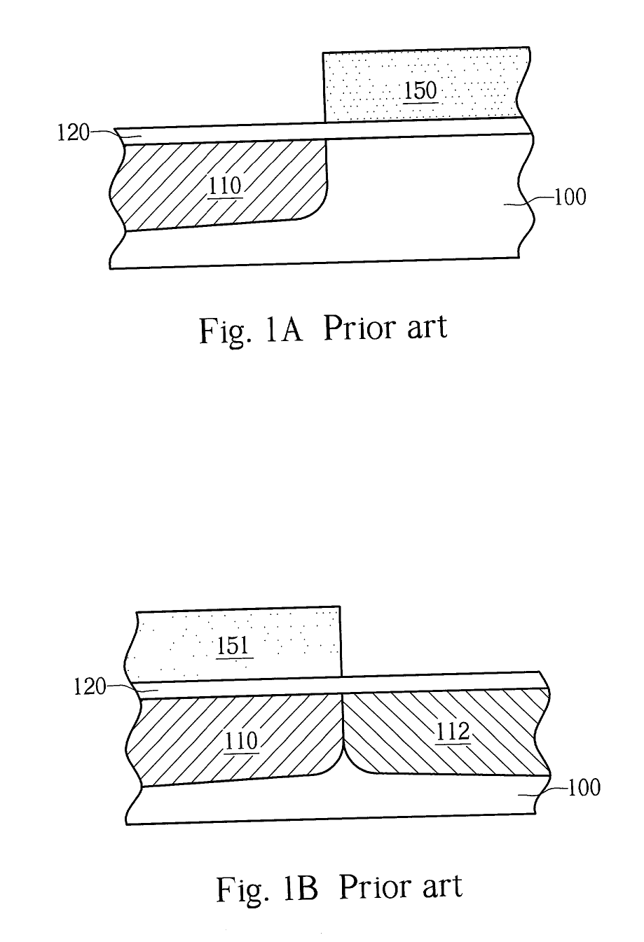

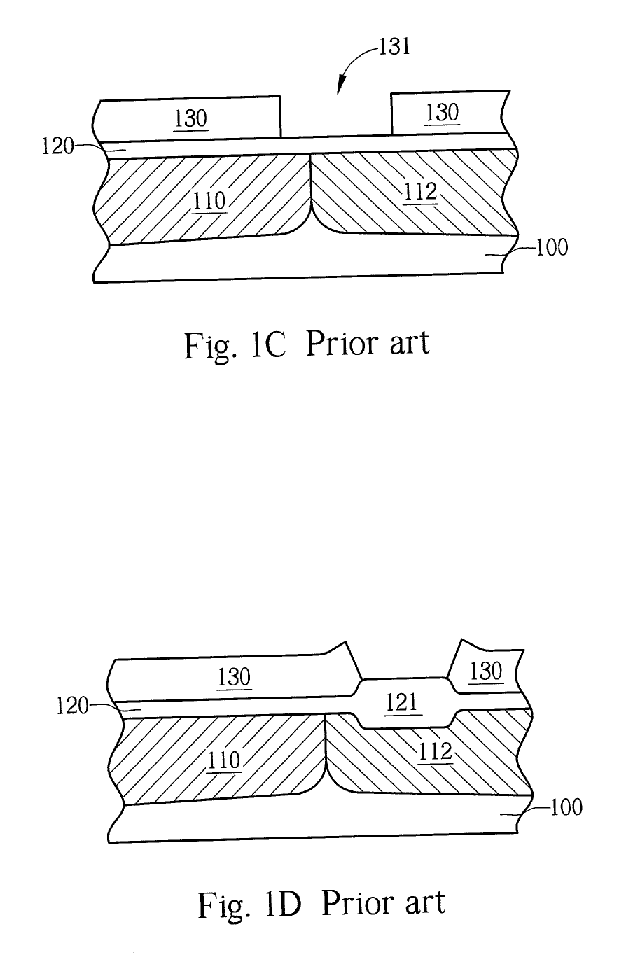

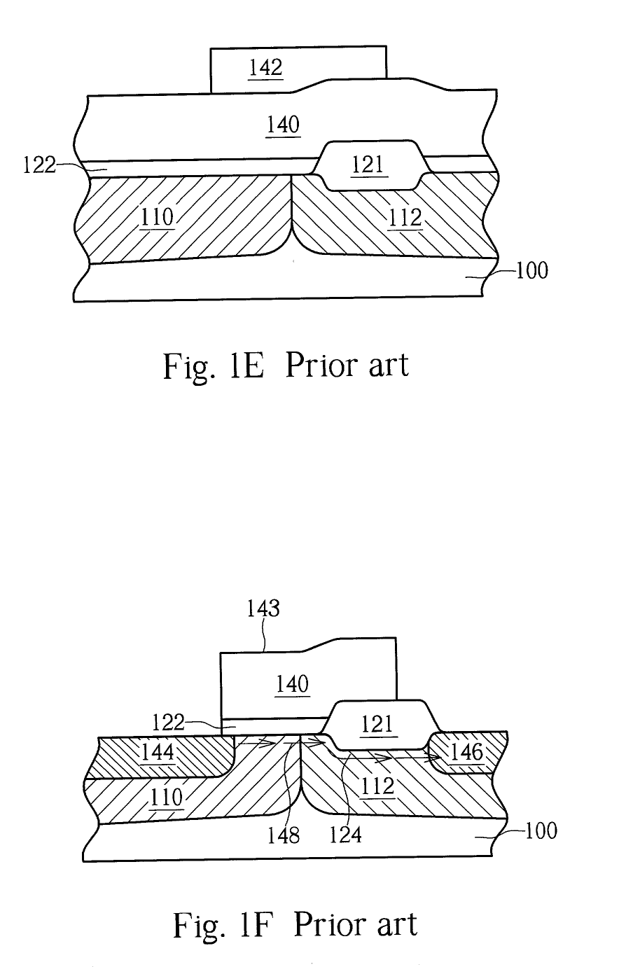

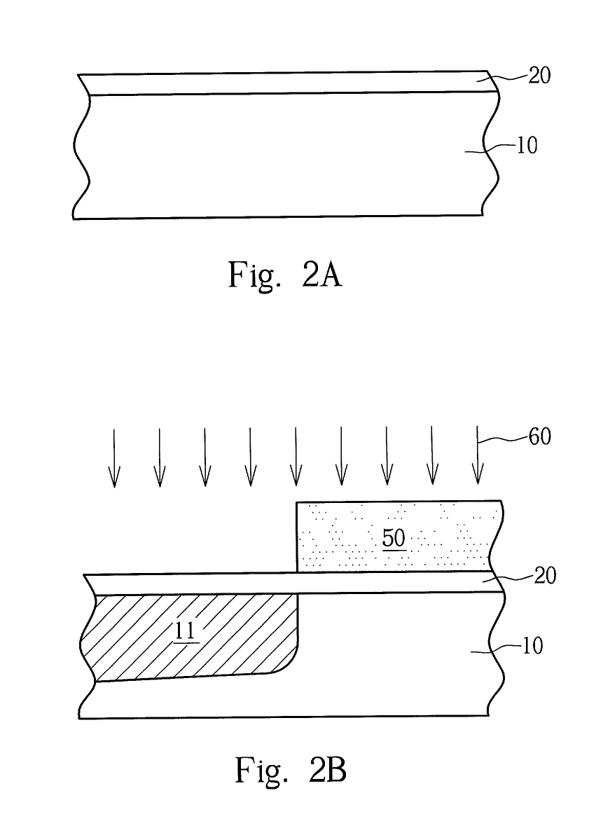

### DETAILED DESCRIPTION OF THE PREFERRED EMBODIMENT

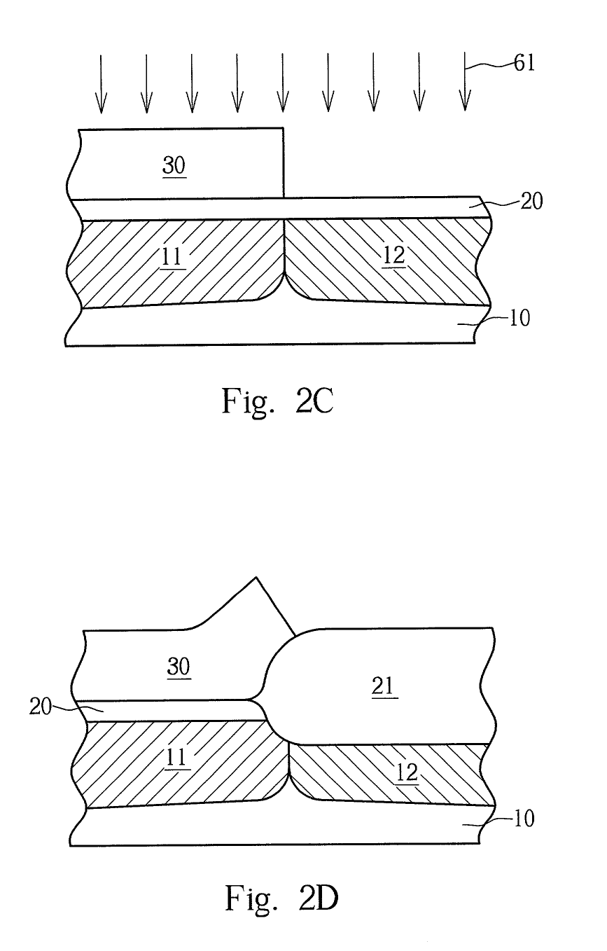

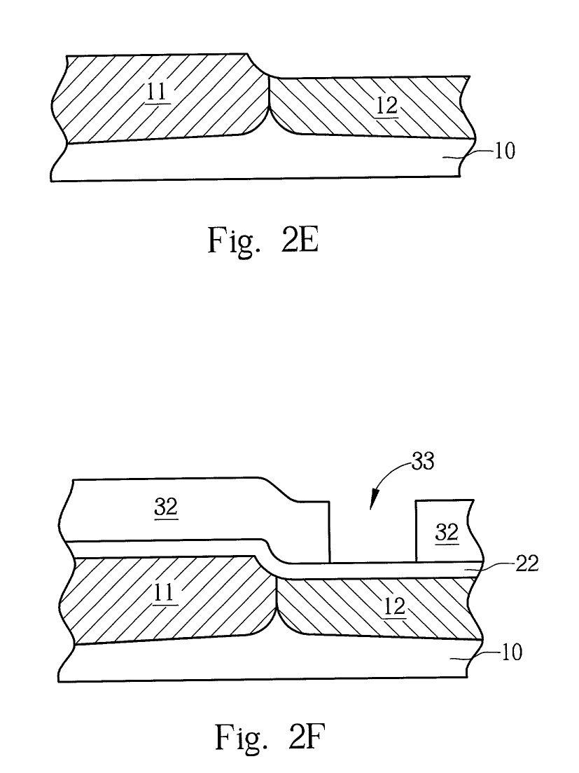

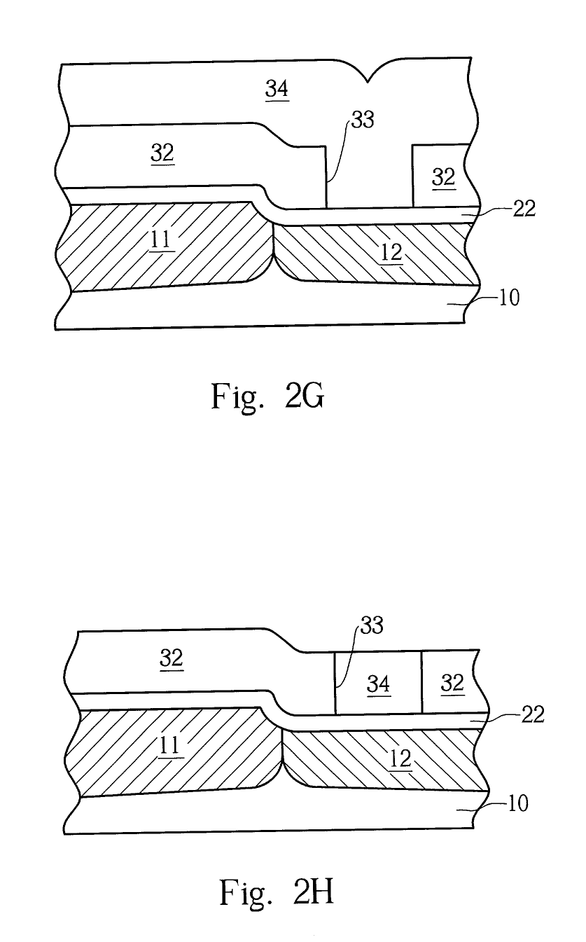

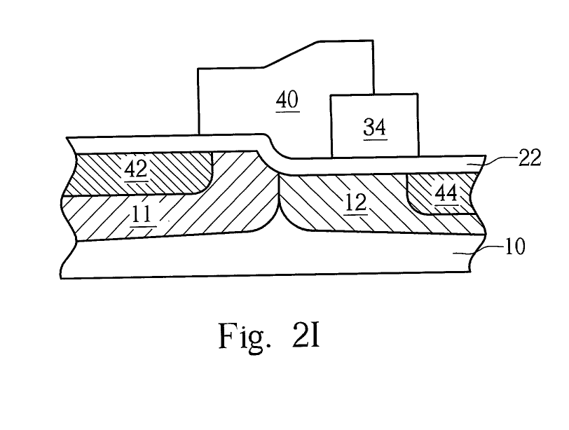

Please refer to FIGS. 2A to 2I. FIGS. 2A to 2I are cross-sectional diagrams of a method of forming an LD MOS transistor on a semiconductor substrate 10 according to the present invention. In a best embodiment of the present invention, the semiconductor substrate 10 is a P-type silicon substrate. The semiconductor substrate 10 is first placed into a thermal oxidation furnace to grow a silicon oxide layer 20, around 100 to 300 Å thick, on the semiconductor substrate 10 using a thermal oxidation process, as shown in FIG. 2A. The silicon oxide layer 20 functions as a pad oxide layer to promote adherence between a subsequent silicon nitride layer and the semiconductor substrate 10, and to reduce thermal stress on the silicon nitride layer. Also, the silicon oxide layer 20 functions as a sacrificial oxide layer in a subsequent ion implantation process to increase the scattering of ions so as to prevent channel effects.

As shown in FIG. 2B, a photoresist layer 50 is coated onto the semiconductor substrate 10. Following that, a lithographic process is performed to define the ion implantation area of a P-well. Using the photoresist layer 50 as a mask, an ion implantation process is performed with a direction 60 to dope P-type dopants into the semiconductor substrate 10 to form a P-type doping region 11. Then the photoresist layer 50 is stripped.

As shown in FIG. 2C, a silicon nitride layer 30 is formed on the semiconductor substrate 10 by CVD. Thereafter, a lithographic process is performed to form a photoresist layer (not shown) on the silicon nitride layer 30 and defines the positions of an N-well in the photoresist layer. Then, the silicon nitride layer 30 is etched along the patterns in the photoresist layer, so as to expose a portion of the surface of the semiconductor substrate 10 for forming the N-well. After the photoresist layer is stripped, an ion implantation process is performed with a direction 61 and uses the remaining silicon nitride layer 30 as a mask, so as to dope N-type dopants into the semiconductor substrate 10 to form an N-type doping region 12 adjacent to the P-type doping region 11.

As shown in FIG. 2D, a thermal treatment is used to drive the dopants in the P-type doping region 11 and the N-type doping region 12 into the semiconductor substrate 10 so as to form the P-well 11 and the N-well 12. During the thermal treatment, the surface of the N-well 12 not covered by the silicon nitride layer 30 is oxidized to grow a field oxide layer 21. As shown in FIG. 2E, subsequently, the silicon nitride layer 30 is stripped using a heated phosphoric acid solution. Then, both the silicon oxide layer 20 and the field oxide layer 21 remaining on the semiconductor substrate 10 are completely removed using a mixture of hydrofluoric acid (HF) and ammonium fluoride (NH₄F)

Following that, as shown in FIG. 2F, the silicon surface, which has suffered atmospheric exposure, is cleaned to ensure its quality. After the cleaning process, the semiconductor substrate 10 is placed into the thermal oxidation furnace again to form a silicon oxide layer 22, around 100 to 250 Å thick, on the active area using a dry oxidation process. A chemical vapor deposition is then performed to deposit a silicon nitride layer 32 with a thickness of 3000 to 6000 Å on the silicon oxide layer 22. Following that, a lithographic process is performed to form a photoresist layer (not shown) on the surface of the silicon nitride layer 32 to define positions for an insulator. Then, using the photoresist layer as a mask, a dry etching process is performed to remove portions of the silicon nitride layer 32, forming an opening 33 within the silicon nitride layer 32. The opening 33 connects to the surface of the silicon oxide layer 22. Alternatively, a wet etching process can be used to remove portions of the silicon nitride layer 32 to form the opening 33.

As shown in FIG. 2G, after the photoresist layer is removed, a deposition process is then performed to deposit a silicon oxide layer 34, around 8000 to 14000 Å thick, on the silicon nitride layer 32, so as to fill the opening 33. In a best embodiment of the present invention, the deposition process of the silicon oxide layer 34 is divided into two steps. A first silicon oxide layer of approximately 3000 to 5000 Å thick is first deposited on both the silicon nitride layer 32 and within the opening 33 by atmospheric pressure chemical vapor deposition (APCVD). Following that, a second silicon oxide layer of approximately 5000 to 9000 Å thick is deposited to cover the first silicon oxide layer by plasma enhanced chemical vapor deposition (PECVD). As a result, the silicon oxide layer 34 is formed by a combination of the first and the second silicon oxide layers.

Thereafter, as shown in FIG. 2H, a chemical mechanical polishing process is performed using the silicon nitride layer 32 as a stop layer to remove portions of the silicon oxide layer 34. Following the chemical mechanical polishing process, the remaining silicon oxide layer 34 in the opening 33 has a surface aligned with the surface of the silicon nitride layer 32, functioning as an insulator. In addition, the remaining silicon oxide layer 34 in the opening 33 may function as a mask for defining positions of a subsequent drain. As shown in FIG. 2I, a polysilicon layer (not shown), around 2000 to 3000 Å thick, is thereafter deposited onto the surfaces of the silicon oxide layers 22 and 34 by LPCVD. A thermal diffusion method or an ion implantation process is then performed to heavily dope the polysilicon layer so as to reduce the resistivity. Following that, a lithographic process and an etching process are performed, respectively, to remove portions of the polysilicon layer, so as to form a gate 40. Wherein, the gate 40 is positioned on a portion of both the P-well 11 and the N-well 12, and one side of the gate 40 is positioned atop the silicon oxide layer 34. Following that, a lithographic process and an ion implantation process are performed to heavily dope the P-well 11 and the N-well 12. As a result, an N-type doping region 42, functioning as a source, is formed on the P-well 11 adjacent to one side of the gate 40. Simultaneously, another N-type doping region 44, functioning as a drain, is formed on the N-well 12 adjacent to one side of the silicon oxide layer 34. Finally, the fabrication process of the LD MOS transistor of the present invention is completed.

In typical high-voltage units, the on-resistance of the gate is related to the channel length of the LD MOS transistor. And the channel length, which is defined as the length from the source to the drain of the LD MOS transistor, is related to the length of the drift region. In the present invention LD MOS transistor, the source 42 is positioned on the P-well 11 adjacent to one side of the gate 40, and the drain 44 is positioned on the N-well 12 adjacent to one side of the silicon oxide layer 34. The channel length of the LD MOS transistor is determined by the two lithographic processes that define positions of the silicon oxide layer 34 and the gate 40 according to the present invention. Hence, both the channel length and the on-resistance of the LD MOS transistor may be precisely controlled according to the present invention.

In contrast to the prior art method of forming the LD MOS transistor, the present invention forms the insulator between the gate and the drain by the deposition and the CMP processes, so the difficulty in controlling the channel length by LOCOS in the prior art is effectively prevented. Since the channel length of the LD MOS transistor can be precisely controlled according to the present invention, the on-resistance can also be well controlled to improve the electrical performance of the LD MOS transistor.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A method of forming a lateral diffused metal-oxide semiconductor (LD MOS) transistor on a semiconductor wafer, the surface of the semiconductor wafer comprising a silicon substrate, a p-well and a n-well both positioned in the silicon substrate and the p-well being adjacent to the n-well, the method comprising:
forming a silicon nitride layer on the silicon substrate;
performing a lithographic process to form a photo-resist layer on the silicon nitride layer, the photo-resist layer being used to define a position of an insulator;
using the photo-resist layer as a mask to perform an etching process to form an opening in the silicon nitride layer;
stripping the photo-resist layer;
performing a deposition process to form a silicon oxide layer on the silicon nitride layer, and filling the opening in the silicon nitride layer;
performing a chemical mechanical polishing (CMP) process to remove portions of the silicon oxide layer to align the surface of the silicon oxide layer with the surface of the silicon nitride layer, wherein the silicon oxide layer remaining in the opening in the silicon nitride layer forms the insulator;
removing the silicon nitride layer;
forming a gate layer positioned on a portion of the surfaces of both the p-well and n-well, and a side of the gate layer positioned on the surface of the insulator; and
performing an ion implantation process to form a doped region positioned on the p-well and a doped region positioned on the n-well, the two doped regions functioning as source and drain of the LD MOS transistor.

2. The method of claim 1 wherein a step of forming a sacrificial layer on the silicon substrate is performed prior to the step of forming the silicon nitride layer.

3. The method of claim 1 wherein the silicon nitride layer has a thickness of about 3000 angstroms to 6000 angstroms.

4. The method of claim 1 wherein the etching process is either a dry etching process or a wet etching process.

5. The method of claim 1 wherein the silicon oxide layer has a thickness of about 8000 to 14000 angstroms.

6. The method of claim 5 wherein the deposition process comprises both an atmospheric pressure chemical vapor deposition (APCVD) process, and a plasma enhanced chemical vapor deposition (PECVD) process.

7. The method of claim 6 wherein the atmospheric pressure chemical vapor deposition (APCVD) process is performed to form the silicon oxide layer of about 3000 angstroms to 5000 angstroms, and the plasma enhanced chemical vapor deposition (PECVD) process is performed to form the silicon oxide layer of about 5000 angstroms to 9000 angstroms.

8. The method of claim 1 wherein the gate layer comprises both a gate oxide layer and a doped polysilicon layer formed on the gate oxide layer.

9. A method of forming a lateral diffused metal-oxide semiconductor (LD MOS) transistor on a semiconductor wafer, the surface of the semiconductor wafer comprising a silicon substrate, the method comprising:
forming both a p-well and a n-well in the silicon substrate, and the p-well being adjacent to the n-well;
forming a first silicon nitride layer on the silicon substrate, the silicon nitride layer comprising an opening within it;
performing a deposition process to form a silicon oxide layer on the first silicon nitride layer, and filling the opening in the first silicon nitride layer;
performing a chemical mechanical polishing (CMP) process to remove portions of the silicon oxide layer to align the surface of the silicon oxide layer with the surface of the first silicon nitride layer, wherein the silicon oxide layer remaining in the opening in the first silicon nitride layer forms the insulator;
removing the first silicon nitride layer;
forming a gate layer positioned on a portion of both the surfaces of the p-well and n-well, and a side of the gate layer positioned on the surface of the insulator; and
performing an ion implantation process to form a doped region positioned on the p-well and a doped region positioned on the n-well, the two doped regions functioning as source and drain of the LD MOS transistor.

10. The method of claim 9 wherein the method of forming the p-well and the n-well in the silicon substrate comprises:
forming a first sacrificial layer on the surface of the silicon substrate;
performing a p-type ion implantation process to form a p-type doped region in a predetermined area of the silicon substrate;
forming a second silicon nitride layer on the first sacrificial layer;
performing a lithographic process to define an ion implantation area of the n-well and to remove the second silicon nitride layer on the ion implantation area;
performing an n-type ion implantation process using the second silicon nitride layer as a mask to form an n-type doped region on the ion implantation area of the silicon substrate; and
performing a thermal oxidation process to form a field oxide layer on the region that is not covered by the second silicon nitride layer and to drive the p-type and n-type dopants into the silicon substrate so as to form the p-well and the n-well, respectively.

11. The method of claim 10 wherein after completing the thermal oxidation process, the method further comprises a step of removing both the first sacrificial layer and the second silicon nitride layer.

12. The method of claim 9 wherein a step of forming a second sacrificial layer on the silicon substrate is performed prior to the step of forming the first silicon nitride layer.

13. The method of claim 9 wherein the first silicon nitride layer has a thickness of about 3000 angstroms to 6000 angstroms.

14. The method of claim 9 wherein the etching process is either a dry etching process or a wet etching process.

15. The method of claim 9 wherein the silicon oxide layer has a thickness of about 8000 to 14000 angstroms.

16. The method of claim 15 wherein the deposition process comprises both an atmospheric pressure chemical vapor deposition (APCVD) process, and a plasma enhanced chemical vapor deposition (PECVD) process.

17. The method of claim 16 wherein the atmospheric pressure chemical vapor deposition (APCVD) process is performed to form the silicon oxide layer of about 3000 angstroms to 5000 angstroms, and the plasma enhanced chemical vapor deposition (PECVD) process is performed to form the silicon oxide layer of about 5000 angstroms to 9000 angstroms.

18. The method of claim 9 wherein the gate layer comprises both a gate oxide layer and a doped polysilicon layer formed on the gate oxide layer.
